(19) United States
(12) Patent Application Publication
(10) Pub. No.: US 2019/0250661 A1
(43) Pub. Date: Aug. 15, 2019

(54) UNIVERSAL VESA ADAPTOR

(71) Applicants: Charles Edward Shirley, Reno, NV (US); Relina Belen DeDios-Shirley, Reno, NV (US)

(72) Inventors: Charles Edward Shirley, Reno, NV (US); Relina Belen DeDios-Shirley, Reno, NV (US)

(21) Appl. No.: 16/273,900

(22) Filed: Feb. 12, 2019

Related U.S. Application Data
(60) Provisional application No. 62/629,488, filed on Feb. 12, 2018.

(51) Int. Cl. G06F 1/16; H05K 5/02; H05K 5/00

(52) U.S. Cl. CPC G06F 1/1601; H05K 5/0017; H05K 5/0204

(57) ABSTRACT

A mount for securing equipment to the back of an audio visual device such as a television having a mounting interface, e.g. a VESA interface, includes one or more adaptor apparatus. The adaptor apparatus includes an attachment portion for attachment to the mounting interface and a receiving portion for securing the equipment, or an equipment holder, to the adaptor. An angled connecting portion between the attachment portion and the receiving portion may allow for additional spacing between the receiving portion and the audio visual device.

### CROSS-REFERENCES TO RELATED APPLICATIONS

This application claims priority to U.S. provisional patent application Ser. No. 62/629,488, filed Feb. 12, 2018, the contents of each of which are herein incorporated by reference.

### FIELD OF THE INVENTION

The present invention is generally related to the field of audio-visual equipment mounts and mounting, and more particularly related to an apparatus for attaching equipment (such as audio-visual equipment) to the back of a display device utilizing the existing VESA-type mount interface built into the display device.

### BACKGROUND OF THE INVENTION

Many types of audio-visual equipment can be utilized in combination with a display device, such as a television or a computer monitor, in order to increase the functionality of the display device. For example, a DVD player may be used in combination with a display device to show recorded movies. Or a video game console may be used in combination with a display device to facilitate playing video games on the display device. These external pieces of audio-visual equipment must be stored in relatively close proximity to the display device during use, which can cause clutter or occupy valuable countertop (or TV-stand) surface space.

Most display devices are manufactured with a mounting interface that can allow for mounting of the display device on a wall or on a display device holding apparatus, such as a swinging monitor arm for example. An example of a widely utilized mounting interface is the VESA system, a universally recognized hole pattern manufactured into the back side of display devices. The standardly configured hole pattern allows for use of third part mounting brackets, stands, etc.

It would be useful, therefore, to utilize the existing mounting interfaces on the back side of most display devices to allow for the holding of, or the concealment of, audio-visual equipment that is intended to be used in combination with the display device.

### BRIEF DESCRIPTION OF THE INVENTION

The herein disclosed universal VESA adaptor apparatus may be used by anchoring the apparatus to a VESA mount interface receiving hole via a screw or bolt, and attaching an adjustable equipment mount to the universal VESA adaptor apparatus. The audio-visual equipment (such as a gaming console or a DVD player, for example) may then be securely held or mounted to the adjustable equipment mount, thus utilizing the existing VESA interface to attach the audio-visual equipment in a fixed position behind the display device.

In one aspect, the invention provides an adaptor interface for use in attaching one or more equipment pieces to a back side of a display device having a mounting interface. The adaptor apparatus may comprise an attachment portion forming a relatively large diameter attachment hole, wherein the relatively large diameter attachment hole is for receiving a screw to attach the adaptor apparatus to one or more holes of the mounting interface on the back side of the display device; receiving portion forming a plurality of relatively small diameter receiving holes for receiving an equipment holder; and a connecting portion spanning between the attachment portion and the receiving portion.

In a preferred embodiment of the present invention, the attachment portion is on a first plane in close proximity to the back side of the display device, the receiving portion is on a second plane spatially separated from the back side of the display device, and the connecting portion is positioned at an angle from the first plane to the second plane.

In one aspect, the invention provides an equipment mount comprising a plurality of adaptors that may be secured to a mounting interface on a back surface of a display device. The plurality of adaptors may comprise an attachment portion comprising an attachment hole, wherein the attachment hole is for receiving a screw to attach the adaptor apparatus to one or more holes of the mounting interface on the back side of the display device. A receiving portion may comprise a plurality of receiving holes for supporting equipment. A connecting portion may span between the attachment portion and the receiving portion. The mounting of the plurality of adaptors to the mounting interface is configurable to support the equipment.

In one aspect, the invention provides a method of securing equipment to the back of a display device having a mounting interface. The method may comprise securing an attachment portion of a first adaptor to the mounting interface and supporting equipment on a receiving portion of the first adaptor comprising a plurality of receiving holes for supporting the equipment.

### BRIEF DESCRIPTION OF THE SEVERAL VIEWS OF THE DRAWING

FIG. 1A includes a photograph of the herein disclosed adaptor apparatus attached to the back side of a display device having an existing mounting interface, in accordance with the present invention;

FIG. 1B includes a photograph of the herein disclosed adaptor apparatus attaching an equipment holder, in accordance with the present invention;

FIG. 1C includes a photograph from a side viewing angle of the herein disclosed adaptor apparatus attaching an equipment holder, in accordance with the present invention;

FIG. 2A illustrates an isometric view of an embodiment of the herein disclosed adaptor apparatus;

FIG. 2B illustrates a reverse angle isometric view of an embodiment of the herein disclosed adaptor apparatus;

FIG. 2C illustrates an isometric view of an alternative embodiment of the herein disclosed adaptor apparatus;

FIG. 2D illustrates a reverse angle isometric view of an alternative embodiment of the herein disclosed adaptor apparatus;

FIG. 3A includes a photograph of the herein disclosed adaptor apparatus attaching an equipment holder that is holding a piece of equipment, in accordance with the present invention;

FIG. 3B includes a photograph of two of the herein disclosed adaptor apparatus attaching an alternative equipment holder, in accordance with the present invention; and

FIG. 4 includes a photograph of equipment being directly mounted to the disclosed adapter apparatus.

### DETAILED DESCRIPTION OF THE INVENTION

The herein disclosed universal VESA adaptor apparatus may be used by anchoring the universal VESA adaptor apparatus to a VESA mount interface receiving hole via a screw or bolt, and attaching an adjustable equipment mount to the universal VESA adaptor apparatus. The audio-visual equipment (such as a gaming console or a DVD player, for example) may then be securely held or mounted to the adjustable equipment mount, thus utilizing the existing VESA interface to attach the audio-visual equipment in a fixed position behind the display device.

Throughout this specification, the phrase “mount interface” will be utilized to refer to VESA mount interfaces and other similar (or similarly intentioned) mounting interfaces that may be built into a display device by the manufacturer. Such mounting interfaces generally include a plurality of holes formed in the back side of the display device.

An exemplary embodiment of the herein disclosed adaptor apparatus for use in attaching one or more equipment pieces to a back side of a display device having a mounting interface comprises: an attachment portion forming a relatively large diameter attachment hole, wherein the relatively large diameter attachment hole is for receiving a screw to attach the adaptor apparatus to one or more holes of the mounting interface on the back side of the display device; a receiving portion forming a plurality of relatively small diameter receiving holes for receiving an equipment holder; and a connecting portion spanning between the attachment portion and the receiving portion. In a preferred embodiment of the present invention, the attachment portion is on a first plane in close proximity to the back side of the display device, the receiving portion is on a second plane spatially separated from the back side of the display device, and the connecting portion is positioned at an angle from the first plane to the second plane.

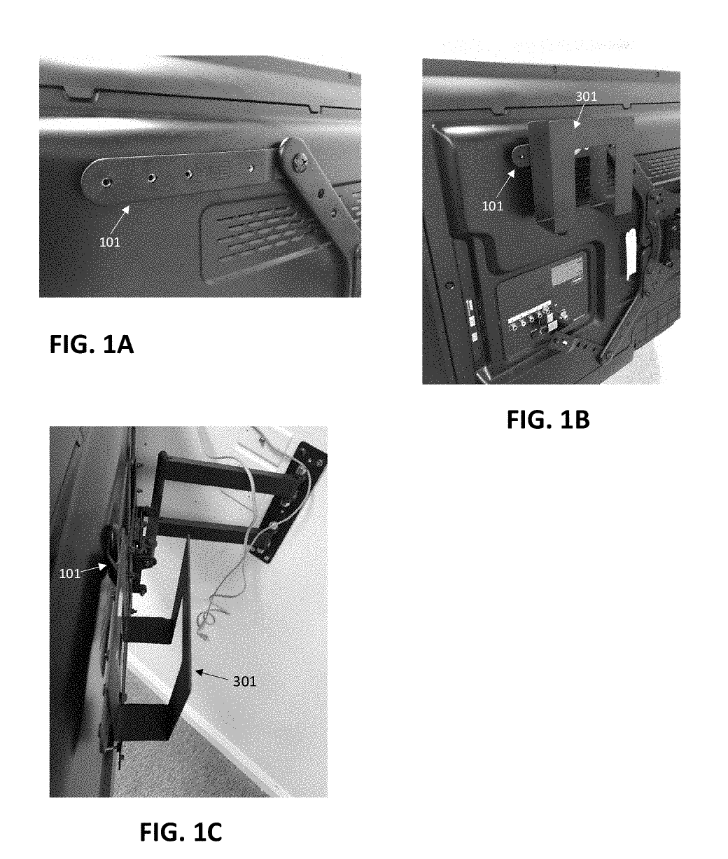

Referring to FIG. 1A, FIG. 1B, and FIG. 1C, the herein disclosed universal VESA adaptor apparatus is shown in use attached to a VESA hole of a display device (a standard computer monitor, in this example). FIG. 1A shows adaptor apparatus 101 attached via a screw to a VESA interface hole of the display device. FIG. 1B shows equipment holder 301 attached to adaptor apparatus 101. And FIG. 1C shows adaptor apparatus 101 securely attaching equipment holder 301 to the display device, from an alternative viewing angle so as to demonstrate the clearance (or spatial separation) between the display device and adaptor apparatus 101 (and therefore the clearance or spatial separation created between the display device and any equipment held in equipment holder 301).

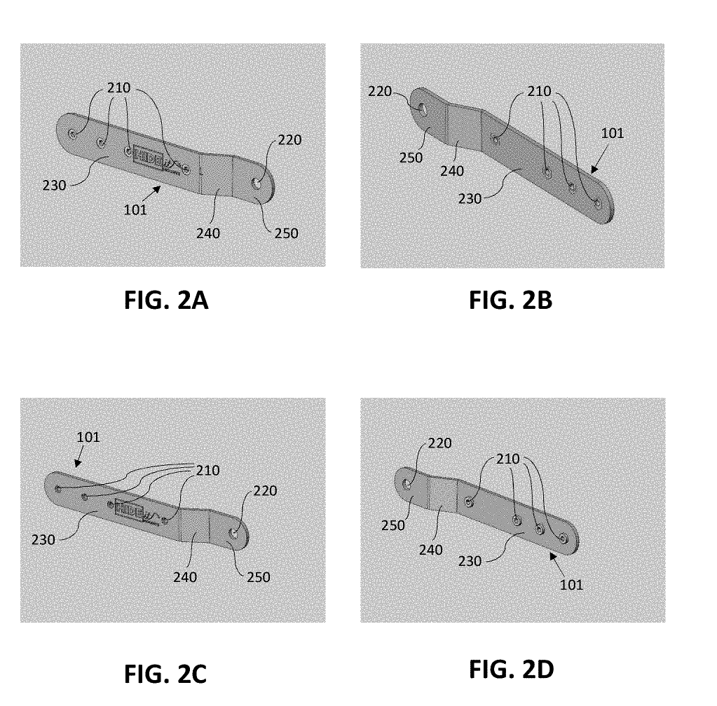

Referring to FIG. 2A, FIG. 2B, FIG. 2C, and FIG. 2D, adaptor apparatus 101 is illustrated in various embodiments and from various viewing angles. Adaptor apparatus 101 includes attachment portion 250, receiving portion 230, and connecting portion 240 spanning from attachment portion 250 to receiving portion 230. In a preferred embodiment of the present invention, attachment portion 250 is on a first plane that is in close physical proximity to the back side of the display device when adaptor apparatus 101 is attached to the mounting interface of the display device. In this preferred embodiment, receiving portion 230 is on a second plane that is relatively spatially separated from the back side of the display device. This spatial separation may be referred to as a clearance. Continuing with this preferred embodiment, connection portion 240 may be angled to span from the first plane of attachment portion 250 to the second plane of receiving portion 230, thus creating the clearance or spatial separation between the display device and any equipment held by equipment holder 301.

Attachment portion 250 forms attachment hole 220. Attachment hole 220 may be of a relatively large diameter when compared to the diameter of the plurality of receiving holes formed by receiving portion 210. Attachment hole 220 is for receiving a screw or a bolt to securely connect (or attach) adaptor apparatus 101 to a mounting interface hole on the back side of a display device. See FIG. 1A for an example of attachment hole 220 receiving a screw to attach adaptor apparatus 101 to the back side of a display device.

Receiving portion 230 includes a plurality of receiving holes 210. Receiving holes 210 may be of a relatively small diameter when compared to the diameter of attachment hole 220. Receiving holes 210 are for receiving screws or bolts for attaching equipment holder 301 to adaptor apparatus 101. In an exemplary embodiment of the present invention, receiving portion 230 includes a plurality of apertures. Receiving nuts then may be pressed or welded into each of the apertures, so as to allow the receiving holes 210 to receive threaded connecting pieces such as screws or bolts. FIG. 2A and FIG. 2B illustrate views from opposing sides of a particular embodiment of the present invention. FIG. 2C and FIG. 2D illustrates views from opposing sides of an alternative embodiment of the present invention wherein the plurality of receiving holes 210 may protrude somewhat from the plane of receiving portion 230.

In one embodiment, the holes 210 may be obrounds (oval holes) which provide some flexibility in attachment points. Because obrounds are not threaded, a nut would need to be used to secure a bolt or stud.

The herein disclosed adaptor apparatus for use in attaching one or more equipment pieces to a back side of a display device having a mounting interface may be formed of any material known in the art that will provide a rigid connection between an equipment holder and the mounting interface. A preferred embodiment of the present invention is formed of steel and powder coated. In an alternative embodiment, the adaptor apparatus may be made of a flexible material, such as a polymer or composite, to provide some flexibility, vibration dampening, electrical isolation, etc.

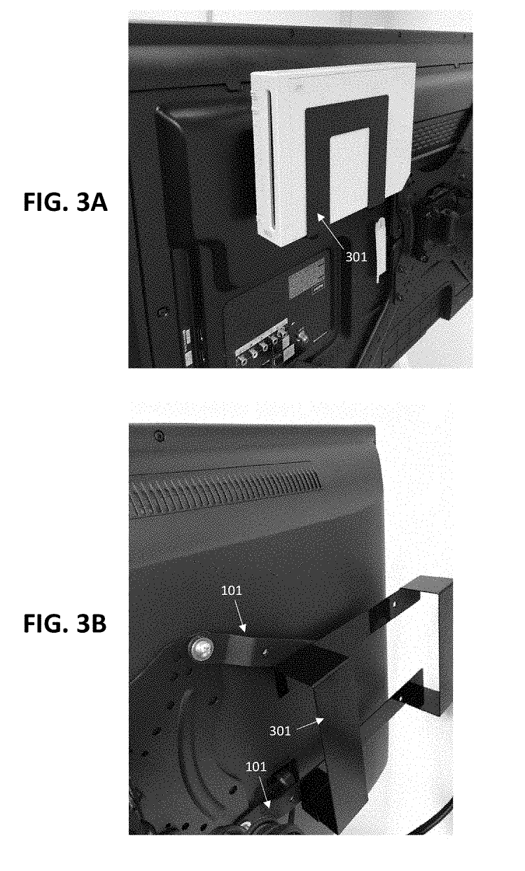

Referring to FIG. 3A, the herein disclosed adaptor apparatus is utilized to attach equipment holder 301 in place behind a display device via the standard mounting interface. Adaptor apparatus 101 cannot be seen in FIG. 3A because the view is impaired by the piece of equipment being held in equipment holder 301 (in this example, the piece of equipment is a video game console). Referring to FIG. 3B, an alternative arrangement utilizes two adaptor apparatus (each labeled as 101) to secure a relatively larger equipment holder 301 in place behind the display device. The equipment holder spans 301 spans between the two adaptors 101 and is secured to each of the two adaptors 101. As will be apparent to those skilled in the art, many types and shapes of equipment holders may be utilized at 301 in order to attach differing types of equipment and all such types of equipment, and equipment holders, are intended to be included herein.

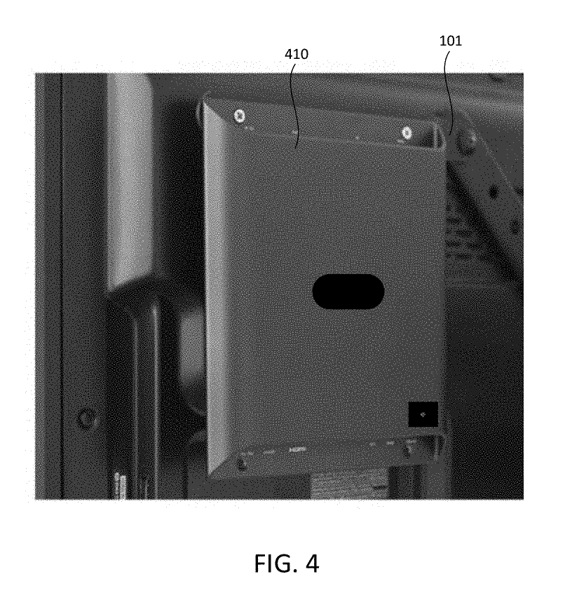

The device being mounted could already have a threaded hole or a nut welded on to the device for receiving a bolt/screw and could therefore be mounted directly to the apparatus without requiring the equipment holder described above. FIG. 4 shows an embodiment where equipment 410 is mounted directly to the apparatus 101.

The apparatus 101 may be configured to extend upward, downward, inward and outward of the mounting interface 52. By moving the apparatus bars 101 closer together, further apart, etc. adjustments can be made to accommodate different sized boxes, equipment and types of equipment. While two apparatus are shown in the Figs., the system can support 1 to 4 bars 101 being utilized.

While the present invention has been illustrated and described herein in terms of a preferred embodiment and several alternatives, it is to be understood that the apparatus described herein can have a multitude of additional uses and applications. Accordingly, the invention should not be limited to just the particular description and various drawing figures contained in this specification that merely illustrate a preferred embodiment and application of the principles of the invention.

What is claimed is:

1. An adaptor apparatus for use in attaching one or more equipment pieces to a back side of a display device having a mounting interface, comprising:
an attachment portion comprising an attachment hole, wherein the attachment hole is for receiving a screw to attach the adaptor apparatus to one or more holes of the mounting interface on the back side of the display device;
a receiving portion comprising a plurality of receiving holes for supporting equipment; and
a connecting portion spanning between the attachment portion and the receiving portion.

2. The adaptor apparatus of claim 1, wherein the attachment portion is on a first plane in close proximity to the display device, the receiving portion is on a second plane spatially separated from the display device, and the connecting portion is positioned at an angle from the first plane to the second plane.

3. The adaptor apparatus of claim 1, wherein a diameter of the attachment hole is larger than a diameter of the receiving holes.

4. The adaptor apparatus of claim 1, wherein one or more of the receiving holes are obrounds.

5. The adaptor apparatus of claim 1 wherein the receiving portion is configured to support an equipment holder that supports the equipment.

6. The adaptor apparatus of claim 1 wherein the receiving portion is configured to support equipment directly connected to the receiving portion.

7. An equipment mount comprising:
a plurality of adaptors that may be secured to a mounting interface on a back surface of a display device, the plurality of adaptors comprising:
an attachment portion comprising an attachment hole, wherein the attachment hole is for receiving a screw to attach the adaptor apparatus to one or more holes of the mounting interface on the back side of the display device;
a receiving portion comprising a plurality of receiving holes for supporting equipment; and
a connecting portion spanning between the attachment portion and the receiving portion;
wherein mounting of the plurality of adaptors to the mounting interface is configurable to support the equipment.

8. The equipment mount of claim 7 wherein the equipment is supported by the plurality of adaptors.

9. The equipment mount of claim 8 wherein the equipment spans between at least two of the plurality of adaptors.

10. The equipment mount of claim 9 wherein the equipment is supported by an equipment holder that is secured to at least two of the adaptors.

11. A method of securing equipment to the back of a display device having a mounting interface, the method comprising:
securing an attachment portion of a first adaptor to the mounting interface;
supporting equipment on a receiving portion of the first adaptor comprising a plurality of receiving holes for supporting the equipment.

12. The method of claim 11 comprising securing a second adaptor to the mounting interface and supporting the equipment between the first adaptor and the second adaptor.

13. The method of claim 12 comprising securing an equipment holder to the first adaptor and the second adaptor and supporting the equipment in the equipment holder.

14. The method of claim 12 comprising securing the equipment directly to the first adaptor and the second adaptor.
